(19) United States
(12) Patent Application Publication
(10) Pub. No.: US 2025/0382706 A1
(43) Pub. Date: Dec. 18, 2025

(54) DEPOSITION SOURCE AND ELECTRONIC DEVICE

(71) Applicant: Samsung Display Co., LTD., Yongin-si (KR)

(72) Inventors: Dong Yun SHIN, Yongin-si (KR); Gan Young PARK, Yongin-si (KR); Seung Joo BAEK, Yongin-si (KR); Jong Hyun JUNG, Yongin-si (KR)

(73) Assignee: Samsung Display Co., LTD., Yongin-si (KR)

(21) Appl. No.: 19/014,756

(22) Filed: Jan. 9, 2025

(30) Foreign Application Priority Data
Jun. 12, 2024 (KR) 10-2024-0076464

(51) Int. Cl. C23C 16/455; H10K 59/12; H10K 71/10

(52) U.S. Cl. CPC C23C 16/45574; C23C 16/4557; H10K 59/1201; H10K 71/10

(57) ABSTRACT

A deposition source may include: a housing; a nozzle component disposed on the housing, and including a first nozzle and a second nozzle adjacent to the first nozzle; a first storage disposed in the housing and that receives a first deposition material; a second storage disposed in the housing and that receives a second deposition material; and a cover disposed between the housing and the nozzle component, and including a first cover and a second cover. The first cover may overlap the first storage without overlapping the second storage, in a plan view.

### CROSS-REFERENCE TO RELATED APPLICATION(S)

The application claims priority to and benefits of Korean patent application number 10-2024-0076464 filed on Jun. 12, 2024, the entire contents of which are incorporated herein by reference.

### BACKGROUND

### 1. Technical Field

Various embodiments relate to a deposition source and electronic device.

### 2. Description of Related Art

With the development of information technology, the importance of display devices, which serve as a connection medium between a user and information, has been emphasized. Owing to the importance of display devices, the use of various kinds of display devices, such as a liquid crystal display device and an organic light emitting display device, has increased.

Electrodes, emission layers, organic layers, inorganic layers, and the like of display devices may be formed by various methods. As a representative example, there is a vacuum deposition method in which a thin film is formed by depositing a certain material in a vacuum atmosphere. The vacuum deposition method may be performed in such a way that a mask is disposed between a deposition source and a target substrate in a chamber, and a deposition material of the deposition source is deposited onto the target substrate by sublimation or vaporization.

### SUMMARY

Various embodiments are directed to a deposition source capable of preventing deposition materials from being mixed in the deposition source, and uniformly depositing different deposition materials onto a target substrate.

However, embodiments are not limited to those set forth herein. The above and other embodiments will become more apparent to one of ordinary skill in the art to which the disclosure pertains by referencing the detailed description of the disclosure given below.

An embodiment may provide a deposition source including: a housing; a nozzle component disposed on the housing, and including a first nozzle and a second nozzle adjacent to the first nozzle; a first storage disposed in the housing and that receives a first deposition material; a second storage disposed in the housing and that receives a second deposition material; and a cover disposed between the housing and the nozzle component, and including a first cover and a second cover. The first cover may overlap the first storage without overlapping the second storage, in a plan view.

In an embodiment, the first cover may cover an upper portion of the first storage. The second cover may cover an upper portion of the second storage.

In an embodiment, the first cover may include a first cover hole. The first storage may include a first storage hole overlapping the first cover hole in a plan view. The second cover may include a second cover hole. The second storage may include a second storage hole overlapping the second cover hole in a plan view.

In an embodiment, a first fastener may be inserted into the first cover hole and the first storage hole. A second fastener may be inserted into the second cover hole and the second storage hole. Each of the first fastener and the second fastener may include a bolt.

In an embodiment, the first storage may include: a first crucible that receives the first deposition material; and a first partition that divides an internal space of the first crucible. The second storage may include: a second crucible that receives the second deposition material; and a second partition that divides an internal space of the second crucible. A height of the first partition may be shorter than a height of the first crucible. A height of the second partition may be shorter than a height of the second crucible.

In an embodiment, the first cover may not contact the first partition. The second cover may not contact the second partition.

In an embodiment, the internal space of the first crucible may be fluidly connected. The internal space of the second crucible may be fluidly connected.

In an embodiment, the deposition source may further include a plate disposed on the cover. The plate may have a plate-like structure extending in a first direction and a second direction intersecting with the first direction. The plate may have a plurality of plate holes.

In an embodiment, the deposition source may further include a partition wall disposed between the first storage and the second storage.

In an embodiment, the first cover may include: a first cover plate extending in a first direction and a second direction intersecting with the first direction; and a first cover protrusion protruding from the first cover plate in a third direction perpendicular to the first direction and the second direction. The second cover may include: a second cover plate extending in the first direction and the second direction; and a second cover protrusion protruding from the second cover plate in the third direction. A side surface of the first cover protrusion may contact a first side surface of the partition wall. A side surface of the second cover protrusion may contact a second side surface of the partition wall different to the first side surface.

In an embodiment, the deposition source may further include a heater disposed adjacent to the housing, and including a first heater and a second heater. The first heater may be connected to a first power supply, and that heats the first storage. The second heater may be connected to a second power supply independent from the first power supply, and that heats the second storage.

The housing may include a housing bottom, and a housing sidewall part bent and extending from the housing bottom. The housing sidewall part may include a housing protrusion protruding toward a sidewall of the housing. The housing protrusion may be disposed between the first storage and the second storage. The deposition source may further include an adiabatic plate disposed in the housing protrusion.

In an embodiment, a vacant space may be defined between the first storage and the second storage. The deposition source may further include an adiabatic plate disposed in the vacant space.

In an embodiment, the first nozzle may include a first nozzle hole. The second nozzle may include a second nozzle hole. The first nozzle and the second nozzle may be alternately arranged.

In an embodiment, the first deposition material may be sprayed from the first nozzle through a first path defined by the first storage, the first cover, the partition wall, and the first nozzle hole. The second deposition material may be sprayed from the second nozzle through a second path defined by the second storage, the second cover, the partition wall, and the second nozzle hole. The first path and the second path may be fluidly separated from each other.

An embodiment may provide a deposition source including: a housing; a nozzle component disposed on the housing, and including a first nozzle and a second nozzle alternately arranged; a first storage disposed in a first side of the housing and that receives a first deposition material; a second storage disposed in a second side of the housing and that receives a second deposition material; a partition wall disposed in the housing, and positioned between the first storage and the second storage; and a heater disposed adjacent to the housing, and including a first heater and a second heater. The first heater may be connected to a first power supply. The second heater may be connected to a second power supply different from the first power supply. The first deposition material may be sprayed from the first nozzle. The second deposition material may be sprayed from the second nozzle. The first deposition material and the second deposition material may be prevented from being mixed with each other in the housing.

In an embodiment, the deposition source may further include: a cover disposed between the housing and the nozzle component, and including a first cover and a second cover; and a partition wall disposed between the first storage and the second storage. The first cover may include: a first cover plate extending in a first direction and a second direction intersecting with the first direction; and a first cover protrusion protruding from the first cover plate in a third direction perpendicular to the first direction and the second direction. The second cover may include: a second cover plate extending in the first direction and the second direction; and a second cover protrusion protruding from the second cover plate in the third direction. The first cover plate may cover an upper portion of the first storage. The second cover plate may cover an upper portion of the second storage. A side surface of the first cover protrusion may contact at least a portion of a first side surface of the partition wall. A side surface of the second cover protrusion may contact at least a portion of a second side surface of the partition wall different to the first side surface.

In an embodiment, the first cover may include a first cover hole. The first storage may include a first storage hole overlapping the first cover hole in a plan view. The second cover may include a second cover hole. The second storage may include a second storage hole overlapping the second cover hole in a plan view. A first fastener may be inserted into the first cover hole and the first storage hole. A second fastener may be inserted into the second cover hole and the second storage hole. Each of the first fastener and the second fastener may include a bolt.

In an embodiment, the deposition source may further include a plate disposed under the nozzle component. The plate may have a plate-like structure extending in a first direction and a second direction intersecting with the first direction. The plate may have a plurality of plate holes.

In an embodiment, a vacant space may be defined between the first storage and the second storage. The deposition source may further include an adiabatic plate disposed in the vacant space. The adiabatic plate may include a metallic material.

An electronic device includes a processor that provides input image data; and a display device that displays an image based on the input image data. The display device may be manufactured by using a deposition source including: a housing; a nozzle component disposed on the housing, and including a first nozzle and a second nozzle adjacent to the first nozzle; a first storage disposed in the housing and that receives a first deposition material; a second storage disposed in the housing and that receives a second deposition material; and a cover disposed between the housing and the nozzle component, and including a first cover and a second cover. The first cover may overlap the first storage without overlapping the second storage, in a plan view.

### BRIEF DESCRIPTION OF THE DRAWINGS

FIGS. 1 and 2 are schematic diagrams for describing a deposition apparatus in accordance with an embodiment.

FIG. 3 is a schematic exploded perspective view illustrating a deposition source in accordance with an embodiment.

FIG. 4 is a schematic perspective view illustrating a housing, a storage, and a partition wall in accordance with an embodiment.

FIG. 5 is a schematic plan view illustrating the housing, the storage, and the partition wall in accordance with an embodiment.

FIG. 6 is a schematic sectional view of a second storage in accordance with an embodiment.

FIG. 7 is a schematic sectional view of the housing in accordance with an embodiment.

FIG. 8 is a schematic sectional view of an adiabatic plate.

FIG. 9 is a schematic sectional view illustrating the housing and the storage in accordance with an embodiment.

FIG. 10 is a schematic view for describing paths of a first deposition material and a second deposition material.

FIG. 11 is a sectional view taken along line A-A′ of FIG. 2.

FIG. 12 is a sectional view taken along line B-B′ of FIG. 2.

FIG. 13 is a schematic plan view illustrating a display device in accordance with an embodiment.

FIG. 14 is a schematic block diagram illustrating an electronic device including a display device in accordance with an embodiment.

FIG. 15 is a schematic diagram illustrating an example where the electronic device of FIG. 14 is a smartphone.

FIG. 16 is a schematic diagram illustrating an example where the electronic device of FIG. 14 is a tablet computer.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

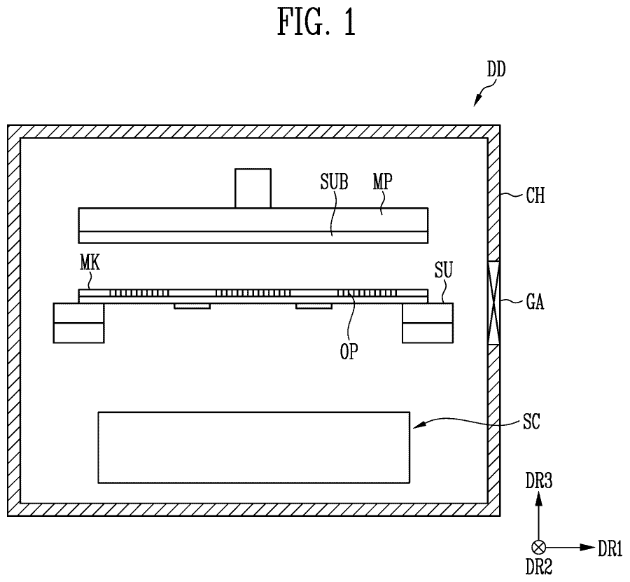

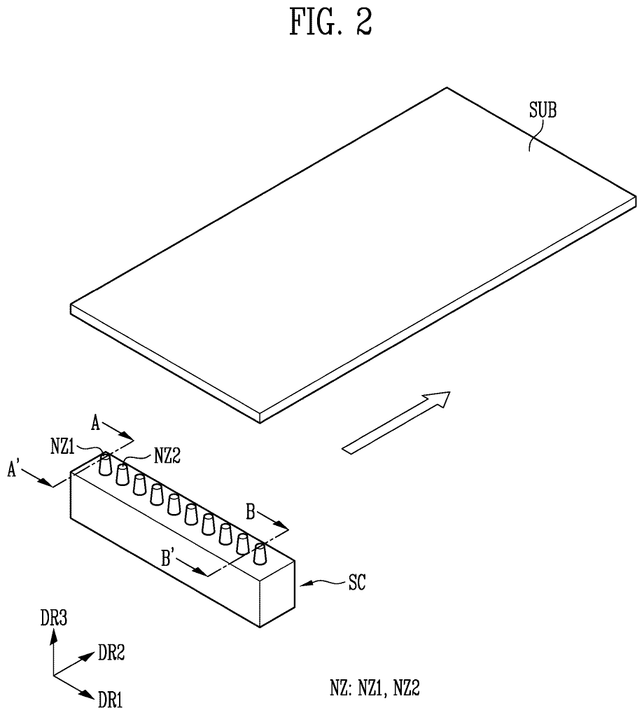

FIGS. 1 and 2 are schematic diagrams for describing a deposition apparatus DD in accordance with an embodiment.

Referring to FIG. 1, the deposition apparatus DD in accordance with an embodiment may include a chamber CH, a moving plate MP, a mask assembly MK, and a deposition source SC.

The deposition apparatus DD may deposit a deposition material onto a target substrate SUB. For example, the target substrate SUB may be a substrate for display devices. The deposition material may include organic material, inorganic material, or the like. For example, the deposition material may be deposited onto the target substrate SUB so as to form an organic light emitting element.

The chamber CH may have an enclosed space therein. The moving plate MP, the mask assembly MK, and the deposition source SC may be disposed in the internal space of the chamber CH. The chamber CH may include one or more gates GA. For example, the gate GA may be disposed in a sidewall of the chamber CH. The gate GA may open or close the chamber CH. For example, the target substrate SUB may be introduced (or supplied) into and removed (or discharged) from the chamber CH through the gate GA.

The moving plate MP may move in the chamber CH. For example, the moving plate MP may move in a first direction DR1, a second direction DR2, a third direction DR3, or other directions, with an upper part of moving plate MP connected to a ceiling of the chamber CH.

The first direction DR1, the second direction DR2, and the third direction DR3 may be perpendicular to each other. Hereinafter, it is assumed that the first direction DR1 and the second direction DR2 intersect with each other and refer to a horizontal direction, and the third direction DR3 refers to a direction perpendicular to the first direction DR1 and the second direction DR2.

The target substrate SUB may be disposed under the moving plate MP. The moving plate MP may use an electrostatic or magnetic force to hold the target substrate SUB. The moving plate MP may move the target substrate SUB in the chamber CH.

The mask assembly MK may be disposed between the target substrate SUB and the deposition source SC. The mask assembly MK may overlap the target substrate SUB. The mask assembly MK may be supported by a support SU disposed in the chamber CH.

Openings OP may be defined in the mask assembly MK. Deposition materials sprayed from the deposition source SC may pass through the openings OP and then be deposited onto the target substrate SUB.

The deposition source SC may be disposed under the mask assembly MK. The deposition source SC may receive a deposition material therein. The deposition source SC may receive deposition materials therein.

The deposition source SC may vaporize or sublimate the deposition material received therein and provide the vaporized or sublimated deposition material to the target substrate SUB.

FIG. 2 is a diagram illustrating a method of moving the deposition source SC shown in FIG. 1. For the sake of convenience in explanation, FIG. 2 illustrates the target substrate SUB and the deposition source SC shown in FIG. 1, while omitting the depiction of the other components.

Referring to FIG. 2, the target substrate SUB may be disposed in the third direction DR3 from the deposition source SC. A surface of the target substrate SUB may face the deposition source SC. A side of the target substrate SUB may extend in the first direction DR1, and another side thereof may extend in the second direction DR2.

For example, the deposition source SC may be a linear deposition source. For example, the deposition source SC may include a nozzle component NZP including nozzles NZ1 and NZ2 arranged in the first direction DR1. The first nozzle NZ1 and the second nozzle NZ2 may be arranged in the first direction DR1. For example, first nozzles NZ1 and second nozzles NZ2 may be alternately arranged adjacent to each other in the first direction DR1.

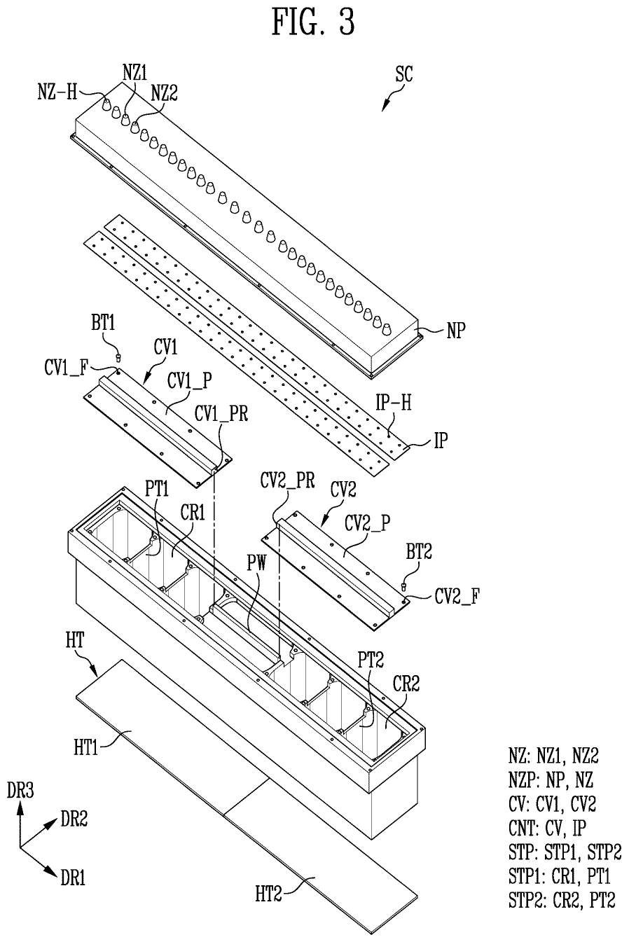

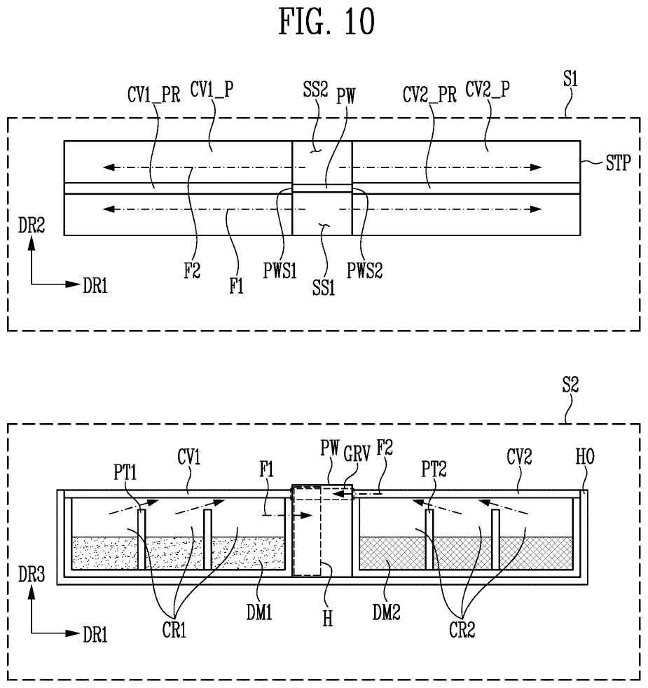

For example, the deposition source SC may include a first deposition material DM1 (refer to FIG. 10) and a second deposition material DM2 (refer to FIG. 10), which are different from each other. In the case where the deposition source SC receives the first deposition material DM1 and the second deposition material DM2 therein, the first nozzles NZ1 may be connected (or fluidly connected) to a first crucible CR1 (refer to FIG. 3) containing the first deposition material DM1, and the second nozzles NZ2 may be connected (or fluidly connected) to a second crucible CR2 (refer to FIG. 3) containing the second deposition material DM2. In the disclosure, the term “fluidly connected” between a first component and a second component means that a substance (e.g., liquid or gas) may flow between the first component and the second component.

However, embodiments are not limited to the aforementioned example. The number of deposition materials that are applied to the deposition source SC is not limited. However, for the sake of convenience in explanation, an example will be described, in which the deposition source SC includes the first deposition material DM1 and the second deposition material DM2.

The deposition source SC may spray the deposition materials while moving in the second direction DR2. Therefore, it is possible to form a thin film on an overall surface of the target substrate SUB.

In FIG. 2, the single deposition source SC is illustrated, but embodiments are not limited thereto. For example, deposition sources SC may be disposed adjacent to each other in the first direction DR1 or the second direction DR2. In the case where deposition sources SC are disposed, it is possible to form a thin film on an overall surface of the target substrate SUB having a large surface area.

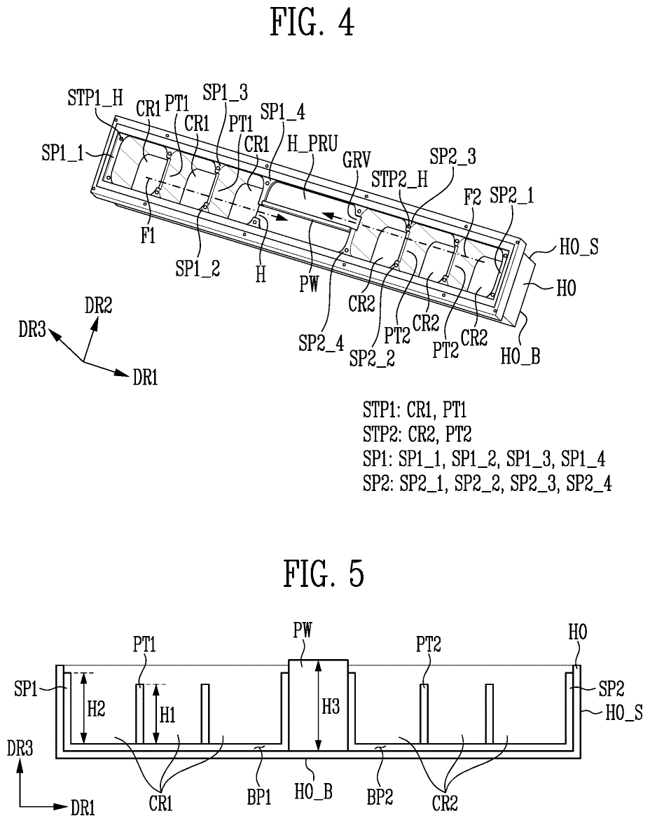

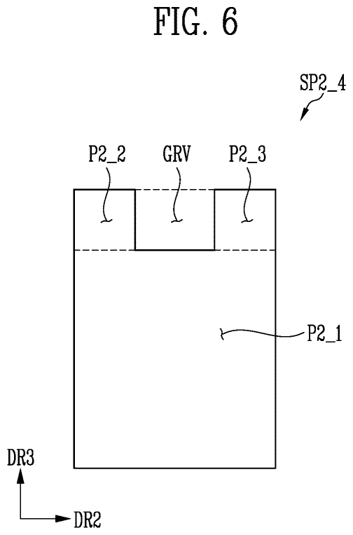

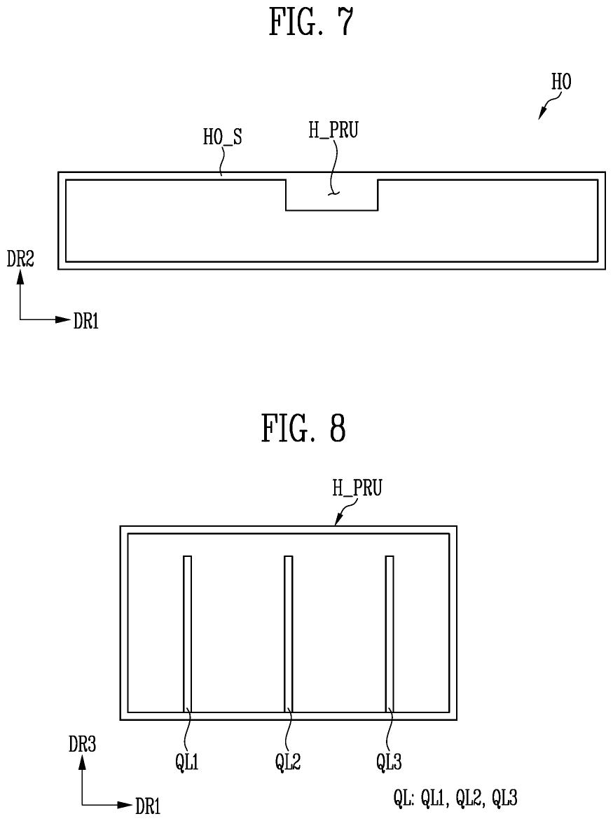

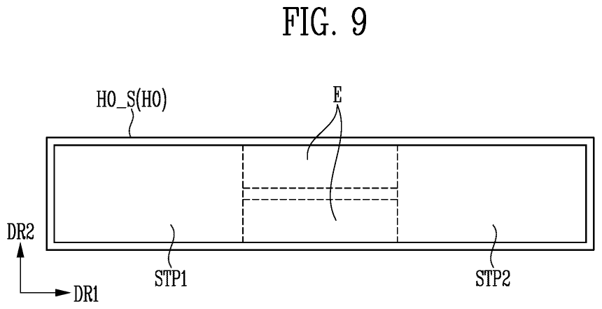

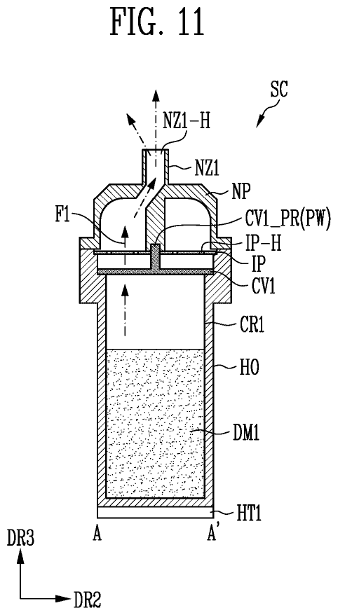

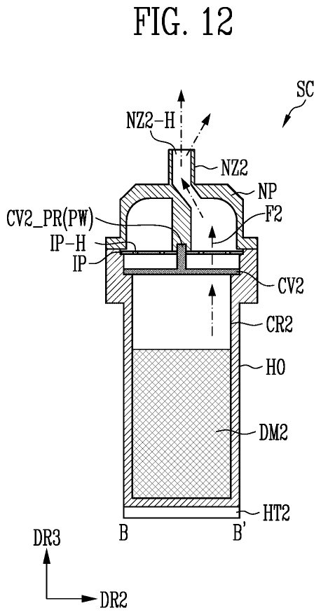

Hereinafter, the deposition source SC in accordance with an embodiment will be described with reference to FIGS. 3 to 12. FIG. 3 is a schematic exploded perspective view illustrating the deposition source SC in accordance with an embodiment. FIG. 4 is a schematic perspective view illustrating a housing HO, a storage STP, and a partition wall (or wall) PW in accordance with an embodiment. FIG. 5 is a schematic plan view illustrating the housing HO, the storage STP, and the partition wall PW in accordance with an embodiment. FIG. 6 is a schematic sectional view illustrating a second storage STP2 in accordance with an embodiment. FIG. 6 shows a sectional view of a 2-4-th partition wall SP2_4 of the second storage STP2. FIG. 7 is a schematic sectional view of the housing HO in accordance with an embodiment. FIG. 8 is a schematic sectional view of an adiabatic plate QL. FIG. 8 illustrates the adiabatic plate QL disposed in a housing protrusion H_PRU. FIG. 9 is a schematic sectional view illustrating the housing HO and the storage STP in accordance with an embodiment. In FIG. 9, for the sake of convenience in explanation, only the housing HO and the storages STP1 and STP2 are illustrated, and detailed configurations of the storages STP1 and STP2 are omitted. FIG. 10 is a schematic view for describing paths of a first deposition material DM1 and a second deposition material DM2. In FIG. 10, S1 illustrates an upper area of the storage STP in a plan view, and S2 illustrates a sectional view of the storage STP. FIG. 11 is a sectional view taken along line A-A′ of FIG. 2. FIG. 12 is a sectional view taken along line B-B′ of FIG. 2.

Referring to FIGS. 3 to 5, the deposition source SC may include the storage STP, the partition wall PW, the housing HO, a connector CNT, a heater HT, and a nozzle component NZP. For example, the deposition source SC in accordance with an embodiment may further include a cooling component disposed adjacent to the heater HT (e.g., to enclose the heater HT), and an angle restriction plate disposed over the nozzle component NZP to adjust a spraying angle of the deposition materials.

The storage STP may be a container for storing (or receiving) deposition materials, and may include the first storage STP1 and the second storage STP2. The first storage STP1 may be a container for receiving the first deposition material DM1. The second storage STP2 may be a container for receiving the second deposition material DM2. The first storage STP1 and the second storage STP2 may be fluidly separated from each other. For example, the first deposition material DM1 contained in the first storage STP1 and the second deposition material DM2 contained in the second storage ST2 may not be mixed with each other.

In an embodiment, the first storage STP1 and the second storage STP2 may be integral with each other. However, embodiments are not limited thereto, and the first storage STP1 and the second storage STP2 may be formed to be separable from each other. In the case where the first storage STP1 and the second storage STP2 are formed to be separable from each other, the deposition source SC may be designed to readily facilitate cleaning.

The first storage STP1 may be a container for storing (or receiving) the first deposition material DM1, and may include a first crucible CR1 that forms an outer shape of the first storage STP1, and a first partition PT1 that divides an internal space of the first crucible CR1 into compartments. At least one first partition PT1 may be provided, thus dividing (or partitioning) the internal space of the first crucible CR1 into separate compartments.

The first crucible CR1 may be provided in a rectangular parallelepiped shape having long sides extending in the first direction DR1, short sides extending in the second direction DR2 perpendicular to the first direction DR1, and a height extending in the third direction DR3 perpendicular to each of the first and second directions DR1 and DR2. For example, the first crucible CR1 may include a first bottom BP1 corresponding to a lower surface of the first crucible CR1, and a first sidewall part SP1 that is bent from the first bottom BP1 and extends at least partially upward. The first sidewall part SP1 may be a portion that determines the height of the first crucible CR1.

The first sidewall part SP1 may include sidewalls. For example, the first sidewall part SP1 may include a 1-1-th sidewall SP1_1, a 1-2-th sidewall SP1_2, a 1-3-th sidewall SP1_3, and a 1-4-th sidewall SP1_4. The 1-1-th sidewall SP1_1 may be a wall contacting an inner surface of the housing HO, and may be a wall disposed parallel to the first partition PT1. The 1-1-th sidewall SP1_1 may be a wall spaced apart from the first partition PT1. Each of the 1-2-th sidewall SP1_2 and the 1-3-th sidewall SP1_3 may be a wall contacting the inner surface of the housing HO, and may be a wall neighboring the 1-1-th sidewall SP1_1. The 1-2-th sidewall SP1_2 and the 1-3-th sidewall SP1_3 may contact the first partition PT1. The 1-4-th sidewall SP1_4 may be a wall disposed parallel to the 1-1-th sidewall SP1_1 and the first partition PT1, and may be a wall disposed closer to the second storage STP2 than is the 1-1-th sidewall SP1_1.

A sidewall of the first sidewall part SP1 may have an opening H. For example, the 1-4-th sidewall SP1_4 of the first sidewall part SP1 may have the opening H. For example, the 1-4-th sidewall SP1_4 and the 1-2-th sidewall SP1_2 may not contact each other, and the opening H may be defined between the 1-4-th sidewall SP1_4 and the 1-2-th sidewall SP1_2. The first deposition material DM1 may flow fluidly through the opening H.

The second storage STP2 may be a container for storing (or receiving) the second deposition material DM2, and may include a second crucible CR2 that forms an outer shape of the second storage STP2, and a second partition PT2 that divides an internal space of the second crucible CR2 into compartments. At least one second partition PT2 may be provided, thus dividing the internal space of the second crucible CR2 into separate compartments.

The second crucible CR2 may be provided in a rectangular parallelepiped shape having long sides extending in the first direction DR1, short sides extending in the second direction DR2, and a height extending in the third direction DR3. For example, the second crucible CR2 may include a second bottom BP2, and a second sidewall part SP2 that is bent and extends from the second bottom BP2. The second sidewall part SP2 may be a portion determining the height of the second crucible CR2.

The second sidewall part SP2 may include sidewalls. For example, the second sidewall part SP2 may include a 2-1-th sidewall SP2_1, a 2-2-th sidewall SP2_2, a 2-3-th sidewall SP2_3, and a 2-4-th sidewall SP2_4. The 2-1-th sidewall SP2_1 may be a wall contacting the inner surface of the housing HO, and may be a wall disposed parallel to the second partition PT2. The 2-1-th sidewall SP2_1 may be a wall spaced apart from the second partition PT2. Each of the 2-2-th sidewall SP2_2 and the 2-3-th sidewall SP2_3 may be a wall contacting the inner surface of the housing HO, and may be a wall neighboring the 2-1-th sidewall SP2_1. The 2-2-th sidewall SP2_2 and the 2-3-th sidewall SP2_3 may contact the second partition PT2. The 2-4-th sidewall SP2_4 may be a wall disposed parallel to the 2-1-th sidewall SP2_1 and the second partition PT2, and may be a wall disposed closer to the first storage STP1 than is the 2-1-th sidewall SP2_1.

A groove GRV may be formed in the 2-4-th sidewall SP2_4. For example, referring to FIG. 6, the 2-4-th sidewall SP2_4 may include a first portion P2_1, a second portion P2_2 protruding from the first portion P2_1, and a third portion P2_3 protruding from the first portion P2_1 in the same direction (e.g., the third direction DR3) as the second portion P2_2. The second portion P2_2 and the third portion P2_3 may be spaced apart from each other, thus defining the groove GRV. The groove GRV may extend in the first direction DR1. The second deposition material DM2 may flow fluidly through the groove GRV.

The groove GRV may not overlap the opening H when viewed in a direction in which the groove GRV extends (e.g., the first direction DR1). The groove GRV and the opening H may be fluidly separated from each other. For instance, the first deposition material DM1 may flow through a first path F1 defined by the first crucible CR1 and the opening H. The second deposition material DM2 may flow through a second path F2 defined by the second crucible CR2 and the groove GRV. The first path F1 and the second path F2 may be fluidly separated from each other so that the first deposition material DM1 and the second deposition material DM2 may be prevented from being mixing with each other in the housing HO. Details pertaining to specific paths of the first path F1 and the second path F2 will be described with reference to FIG. 10 and the subsequent drawings.

The first partition PT1 and the second partition PT2 may each be provided in a plate-like shape with a plane parallel to a plane defined in the second direction DR2 and the third direction DR3, and may traverse the long sides of the first crucible CR1 and the second crucible CR2, respectively. For example, each of the first partition PT1 and the second partition PT2 may have a plate-like structure extending in the second direction DR2 and the third direction DR3. However, embodiments are not limited to the aforementioned example. In an embodiment, the first partition PT1 and the second partition PT2 may traverse the short sides of the first crucible CR1 and the second crucible CR2.

The first partition PT1 and the second partition PT2 may be integral with the first crucible CR1 and the second crucible CR2, respectively. However, embodiments are not limited to the aforementioned example, and the first partition PT1 and the second partition PT2 may be separably assembled with the first crucible CR1 and the second crucible CR2, respectively.

A length of each of the first partition PT1 and the second partition PT2 extending in the third direction DR3 (hereinafter, a height H1 of each of the first partition PT1 and the second partition PT2) may be shorter than a length of each of the first crucible CR1 and the second crucible CR2 extending in the third direction DR3 (hereinafter, a height H2 of each of the first crucible CR1 and the second crucible CR2). For example, the internal compartments of the first crucible CR1 that are separated from each other by the first partition PT1 may be fluidly connected to each other. For example, the first deposition material DM1 when sublimated or vaporized may move between the internal compartments of the first crucible CR1 that are separated from each other by the first partition PT1. The internal compartments of the second crucible CR2 that are separated from each other by the second partition PT2 may be fluidly connected to each other. For example, the second deposition material DM2 when sublimated or vaporized may move between the internal compartments of the second crucible CR2 that are separated from each other by the second partition PT2.

The partition wall PW may be disposed between the first storage STP1 and the second storage STP2. In an embodiment, the partition wall PW may be assembled with the first storage STP1 and the second storage STP2. In an embodiment, the partition wall PW may be assembled with the housing HO. In another example, the partition wall PW may be integral with the first storage STP1 and the second storage STP2. In an embodiment, the partition wall PW may be integral with the housing HO.

The partition wall PW may extend between the first storage STP1 and the second storage STP2 in a direction (e.g., the first direction DR1) in which the first storage STP1 and the second storage STP2 are spaced apart from each other. The partition wall PW may extend in a direction (e.g., the first direction DR1) intersecting with a direction (e.g., the second direction DR2) in which the first partition PT1 and the second partition PT2 extend. For example, the partition wall PW may be provided in a plate-like shape with a plane parallel to a plane defined in the first direction DR1 and the third direction DR3.

A length of the partition wall PW extending in the third direction DR3 (hereinafter, a height H3 of the partition wall PW) may be greater than a height H2 of each of the first crucible CR1 and the second crucible CR2. The height H3 of the partition wall PW may be greater than the height H2 of each of the first crucible CR1 and the second crucible CR2. The partition wall PW may prevent the first deposition material DM1 and the second deposition material DM2 from being mixed with each other. For example, the partition wall PW may fluidly separate the first path F1 from the second path F2. For example, the partition wall PW may separate an area fluidly connected to the opening H from an area fluidly connected to the groove GRV. For example, the first deposition material DM1 flowing through the opening H and the second deposition material DM2 flowing through the groove GRV may be separated from each other by the partition wall PW. As a result, the first deposition material DM1 and the second deposition material DM2 may be prevented from being mixed with each other.

The housing HO may receive the storage STP and the partition wall PW. The storage STP and the partition wall PW may be disposed in the housing HO. For example, the first storage STP1 may be disposed at a side in the housing HO, and the second storage STP2 may be disposed at another side in the housing HO, with the partition wall PW disposed between the first storage STP1 and the second storage STP2 in the housing HO.

The housing HO may be provided in a rectangular parallelepiped shape having long sides extending in the first direction DR1, short sides extending in the second direction DR2, and a height extending in the third direction DR3. The housing HO may include a housing bottom HO_B corresponding to a lower surface of the housing HO, and a housing sidewall part HO_S that is bent and extends from the housing bottom HO_B.

In an embodiment, the housing sidewall part HO_S may include a housing protrusion H_PRU. Referring to FIG. 7, the housing protrusion H_PRU may protrude from the housing sidewall part HO_S. However, a sidewall of the housing sidewall part HO_S may protrude from an area between an end portion and a remaining end portion of a sidewall of the housing HO in a direction opposite to the second direction DR2. The housing protrusion H_PRU may be disposed between the first storage STP1 and the second storage STP2. The housing protrusion H_PRU may not overlap the opening H when viewed in the first direction DR1.

Referring to FIG. 8, the interior of the housing protrusion H_PRU may be formed as a vacant space. In an embodiment, the adiabatic plate QL may be disposed in the vacant space in the housing protrusion H_PRU. According to embodiments, the deposition source SC may further include the adiabatic plate QL. The adiabatic plate QL may be disposed between the first storage STP1 and the second storage STP2.

In an embodiment, adiabatic plates QL may be provided. Embodiments are not limited to the aforementioned example, and a single adiabatic plates QL may be provided. The following description will be based on an embodiment where three adiabatic plates QL are provided.

The adiabatic plate QL may include a first adiabatic plate QL1, a second adiabatic plate QL2, and a third adiabatic plate QL3. The first adiabatic plate QL1, the second adiabatic plate QL2, and the third adiabatic plate QL3 may be disposed to be spaced apart from each other. The first adiabatic plate QL1 may be disposed adjacent to the first storage STP1. For example, the first adiabatic plate QL1 may be disposed closer to the first storage STP1 than is the third adiabatic plate QL3. The third adiabatic plate QL3 may be disposed adjacent to the second storage STP2. For example, the third adiabatic plate QL3 may be disposed closer to the second storage STP2 than is the first adiabatic plate QL1. The second adiabatic plate QL2 may be disposed between the first adiabatic plate QL1 and the third adiabatic plate QL3.

Each of the first adiabatic plate QL1, the second adiabatic plate QL2, and the third adiabatic plate QL3 may be provided in a plate-like shape having a plane parallel to the plane defined in the second direction DR2 and the third direction DR3. However, embodiments are not limited to the aforementioned example, and each of the first adiabatic plate QL1, the second adiabatic plate QL2, and the third adiabatic plate QL3 may be provided in various shapes.

The adiabatic plate QL may include a thermal insulation material. Each of the first adiabatic plate QL1, the second adiabatic plate QL2, and the third adiabatic plate QL3 may include a thermal insulation material. For example, the adiabatic plate QL may include a metallic material. Each of the first adiabatic plate QL1, the second adiabatic plate QL2, and the third adiabatic plate QL3 may include a thermal insulation material. For example, the adiabatic plate QL (i.e., each of the first adiabatic plate QL1, the second adiabatic plate QL2, and the third adiabatic plate QL3) may include at least one of manganese (Mn), titanium (Ti), ZrO₂, Al₂O₃, TiO₂, boron nitride (PBN), aluminum nitride (AlN), and steel use stainless (SUS).

The adiabatic plate QL may prevent heat exchange between the first storage STP1 and the second storage STP2. For example, the temperature of each the first storage STP1 and the second storage STP2 may be independently and readily controlled.

The embodiments have been described in which the housing HO includes the housing protrusion H_PRU protruding from the housing sidewall part HO_S, and the adiabatic plate QL is disposed in the housing protrusion H_PRU, but embodiments are not limited thereto. For example, the referring to FIG. 9, the housing HO may not include the housing protrusion H_PRU.

For example, a vacant space E may be defined between the first storage STP1 and the second storage STP2. For example, an area of an end portion of the 1-4-th sidewall SP1_4 and an area of an end portion of the 2-4-th sidewall SP2_4 may extend to be connected to each other. A lower area of a portion, in which the area of the end portion of the 1-4-th sidewall SP1_4 and the area of the end portion of the 2-4-th sidewall SP2_4 are connected to each other, may define the vacant space E.

In FIG. 9, although vacant spaces E are formed, embodiments are not limited thereto. In an embodiment, a single vacant space E may be provided.

The adiabatic plate QL may be provided to the vacant space E (e.g., disposed in the vacant space E), thereby preventing heat exchange between the first storage STP1 and the second storage STP2.

The connector CNT may be mounted on the storage STP. The connector CNT may be disposed between the storage STP and the nozzle component NZP. The connector CNT may be disposed under the nozzle component NZP.

The connector CNT may include a cover CV and a plate IP. The cover CV may be mounted (or disposed) on the storage STP. The plate IP may be mounted (or disposed) on the cover CV. The plate IP may be mounted (or disposed) under the nozzle component NZP.

The cover CV may include a first cover CV1 and a second cover CV2. The first cover CV1 may include a first cover plate CV1_P having a plate-like structure with long sides extending in the first direction DR1 and short sides extending in the second direction DR2, and a first cover protrusion CV1_PR protruding from the first cover plate CV1_R in the third direction DR3. The second cover CV2 may include a second cover plate CV2_P having a plate-like structure with long sides extending in the first direction DR1 and short sides extending in the second direction DR2, and a second cover protrusion CV2_PR protruding from the second cover plate CV2_R in the third direction DR3.

The first cover CV1 may include a first cover hole CV1_F formed in a perimeter of the first cover CV1. The second cover CV2 may include a second cover hole CV2_F formed in a perimeter of the second cover CV2. Each of the first cover CV1 and the second cover CV2 may be multiple. However, embodiments are not limited to the aforementioned example, and each of the first over hole CV1_F and the second cover hole CV2_F may be singular.

The first cover hole CV1_F may be disposed to overlap a first storage hole STP1_H included in the first storage STP1. The first storage hole STP1_H may be formed along an upper edge of the first storage STP1 (or the first crucible CR1). A first fastener BT1 (see, e.g., FIG. 3) may be inserted into the first cover hole CV1_F and the first storage hole STP1_H. The first fastener BT1 may include a bolt. In another example, the first fastener BT1 may further include a metal seal. The first fastener BT1 may fasten the first cover CV1 to the first storage STP1.

The first cover CV1 may be mounted (or fastened) on the first storage STP1 (or the first crucible CR1). The first cover CV1 may be mounted on the first storage STP1 to overlap the first storage STP1 in a plan view. For example, in a plan view, the first cover CV1 may overlap the first storage STP1 but not overlap the second storage STP2. For example, the first cover CV1 may cover an upper portion of the first storage STP1. The first cover CV1 may contact the edge of the first crucible CR1 but not contact the first partition PT1.

The first cover CV1 may be mounted on the first storage STP1, and a side surface of the first cover protrusion CV1_PR of the first cover CV1 may contact a side surface PWS1 (e.g., first side surface) of the partition wall PW.

The second cover hole CV2_F may be disposed to overlap a second storage hole STP2_H included in the second storage STP2. The second storage hole STP2_H may be formed along an upper edge of the second storage STP2 (or the second crucible CR2). A second fastener BT2 (see, e.g., FIG. 2) may be inserted into the second cover hole CV2_F and the second storage hole STP2_H. The second fastener BT2 may include a bolt. In another example, the second fastener BT2 may further include a metal seal. The second fastener BT2 may fasten the second cover CV2 to the second storage STP2.

The second cover CV2 may be mounted (or fastened) on the second storage STP2 (or the second crucible CR2). The second cover CV2 may be mounted on the second storage STP2 to overlap the second storage STP2 in a plan view. For example, in a plan view, the second cover CV2 may overlap the second storage STP2 but not overlap the first storage STP1. For instance, the second cover CV2 may cover an upper portion of the second storage STP2. The second cover CV2 may contact the edge of the second crucible CR2 but not contact the second partition PT2.

The second cover CV2 may be mounted on the second storage STP2, and a side surface of the second cover protrusion CV2_PR of the second cover CV2 may contact another side surface PWS2 (e.g., second side surface) of the partition wall PW. A side surface of the partition wall PW that contacts a side surface of the second cover protrusion CV2_PR (e.g., a right side surface of the partition wall PW along the first direction DR1) may be different from a side surface of the partition wall PW that contacts a side surface of the first cover protrusion CV1_PR (e.g., a left side surface of the partition wall PW along the first direction DR1).

Each of the first cover CV1 and the second cover CV2 may not overlap the partition wall PW in a plan view. Each of the first cover CV1 and the second cover CV2 may not cover an upper portion of the partition wall PW.

The first cover CV1, the partition wall PW, and the second cover CV2 may fluidly divide an upper space of the storage STP into separate sections. For example, referring to S1 of FIG. 10, the side surface of the first cover protrusion CV1_PR may contact the left side surface of the partition wall PW, and the side surface of the second cover protrusion CV2_PR may contact the right side surface of the partition wall PW. The first cover protrusion CV1_PR, the partition wall PW, and the second cover protrusion CV2_PR may traverse the upper space of the storage STP in the first direction DR1, in a plan view. The upper space of the storage STP may be fluidly divided (or separated) into separate sections by the first cover protrusion CV1_PR, the partition wall PW, and the second cover protrusion CV2_PR that are disposed in the first direction DR1. For example, with respect to an area where the first cover protrusion CV1_PR, the partition wall PW, and the second cover protrusion CV2_PR are disposed, when the second direction DR2 is oriented upward, the first deposition material DM1 may flow along an area SS1 disposed at a lower side while the second deposition material DM2 may flow along an area SS2 disposed at an upper side.

The first cover CV1 and the partition wall PW may define at least a portion of the first path F1 along which the first deposition material DM1 may flow. The second cover CV2 and the partition wall PW may define at least a portion of the second path F2 along which the second deposition material DM2 may flow. Referring to S2 of FIG. 10, the first cover CV1 may cover the upper portion of the first storage STP1, and the second cover CV2 may cover the upper portion of the second storage STP2, thereby fluidly separating the first path F1 and the second path F2 from each other. For example, vaporized first deposition material DM1 may flow along a lower surface of the first cover CV1, and flow through the opening H of the first crucible CR1. For example, vaporized second deposition material DM2 may flow along a lower surface of the second cover CV2, and flow through the groove GRV of the second crucible CR2. The opening H and the groove GRV may be separated from each other by the partition wall PW to prevent the first deposition material DM1 and the second deposition material DM2 from being mixed with each other.

The plate IP may be disposed between the cover CV and the nozzle component NZP. The plate IP may be disposed under the nozzle component NZP. The plate IP may be provided in a plate-like shape having plate holes IP-H. For example, the plate IP may be provided as a plate-like structure that has long sides extending in the first direction DR1 and short sides extending in the second direction DR2 and includes plate holes IP-H. The plate holes IP-H may have various shapes and shapes.

The plate IP may adjust the pressures of the deposition materials DM1 and DM2. For instance, the plate IP may adjust movement directions or flow rates of the deposition materials DM1 and DM2 according to the size, shape, and arrangement of the plate holes IP-H. The plate IP enables each of the vaporized first deposition material DM1 and the vaporized second deposition material DM2 to have a uniform pressure in a direction (e.g., the first direction DR1).

The heater HT may be disposed adjacent to the storage STP, and may heat the storage STP to heat the deposition materials DM1 and DM2 received in the storage STP. For example, the heater HT may be disposed under the housing HO to overlap the storage STP. In another example, the heater HT may be disposed in the housing HO to overlap the storage STP. An arrangement relationship between the heater HT and the housing HO is not limited to a specific example. In an embodiment, the heater HT may be disposed on an outer or inner side surface of the housing HO.

The heater HT may include a first heater HT1 and a second heater HT2. The first heater HT1 may be disposed on a side of the heater HT. The second heater HT2 may be disposed on the other side of the heater HT. The first heater HT1 and the second heater HT2 may be spatially separated from each other in the single heater HT.

The first heater HT1 and the second heater HT2 may not partition the space between the first storage ST1 and the second storage ST2. For example, the first heater HT1 and the second heater HT2 may not be disposed between the first storage ST1 and the second storage ST2. In the conventional art, the first heater HT1 and the second heater HT2 are disposed to enclose the first storage ST1 and the second storage ST2, so that the first heater HT1 and the second heater HT2 are positioned between the first storage ST1 and the second storage ST2. Hence, the first storage ST1 and the second storage ST2 are partitioned from each other by the first heater HT1 and the second heater HT2. Since the first storage ST1 and the second storage ST2 are partitioned from each other by the first heater HT1 and the second heater HT2, the distance between the first storage ST1 and the second storage ST2 may increase, thus leading to a disadvantage of an increase in intervals (or distances) between the nozzles NZ.

In deposition source SC according to an embodiment, the first heater HT1 and the second heater HT2 may not partition the space between the first storage ST1 and the second storage ST2, thereby reducing the distance between the first storage ST1 and the second storage ST2, resulting in a reduction in intervals (or distances) between the nozzles NZ. For example, the distance between the first nozzle NZ1 and the second nozzle NZ2 may be reduced. The first deposition material DM1 and the second deposition material DM2 that are respectively discharged (or sprayed) from the first nozzle NZ1 and the second nozzle NZ2 may be uniformly mixed with each other, thereby making it possible to form a uniform deposition layer.

The first heater HT1 may be connected to a first power supply, and may be supplied with first power (or a first signal). The first power may be provided to heat the first heater HT1. The first heater HT1 may be heated by the first power. The first heater HT1 heated may heat the first storage STP1. The first heater HT1 may heat the first storage STP1, whereby the first deposition material DM1 contained in the first storage STP1 may be vaporized or sublimated by heat.

The second heater HT2 may be connected to a second power supply different (or independent) from the first power supply, and may be supplied with second power (or a second signal). The second power may be provided to heat the second heater HT2. The second heater HT2 may be heated by the second power. The second heater HT2 heated may heat the second storage STP2. The second heater HT2 may heat the second storage STP2, whereby the second deposition material DM2 contained in the second storage STP2 may be vaporized or sublimated by heat.

The first power supply and the second power supply may be independent from each other, and may respectively independently supply power to the first heater HT1 and the second heater HT2. For example, the first heater HT1 and the second heater HT2 may be independently operated. For instance, a heating temperature of the first heater HT1 may be adjusted to a temperature at which the first deposition material DM1 may be vaporized or sublimated, while a heating temperature of the second heater HT2 may be adjusted to a temperature at which the second deposition material DM2 may be vaporized or sublimated. For example, the amount of thermal energy applied to the first storage STP1 from the first heater HT1 may differ from the amount of thermal energy applied to the second storage STP2 from the second heater HT2. For example, internal temperatures of the first storage STP1 and the second storage STP2 may differ from each other.

The nozzle component NZP may be mounted on the housing HO to spray the deposition materials. The nozzle component NZP may include a nozzle plate NP, and at least one nozzle NZ protruding from the nozzle plate NP.

The nozzle plate NP may have a plane substantially parallel to the bottoms BP1 and BP2 of the crucibles CR1 and CR2 and the housing bottom HO_B of the housing HO, and may be seated over the housing sidewall part HO_S of the housing HO.

Nozzles NZ may be provided. The nozzles NZ may include first nozzles NZ1 and second nozzles NZ2. The first nozzles NZ1 and the second nozzles NZ2 may or may not be alternately arranged at regular intervals (or distances) in the first direction DR1. The intervals (or distances) of the nozzles NZ may vary according to the kind of deposition material, the size of the storage STP, the size of a target substrate for deposition, or the like.

Each of the nozzles NZ may have a nozzle hole NZ-H passing through the nozzle plate NP. The deposition materials contained in the storage STP may be sprayed out of the deposition source SC through the nozzles NZ and deposited onto the target substrate SUB. According to embodiments, the nozzle hole NZ-H may be formed in various ways. For example, the nozzle hole NZ-H may be formed through penetration in a direction perpendicular to a plane on which the nozzle plate NP is disposed. In another example, the nozzle hole NZ-H may be formed through penetration in a direction inclined relative to the plane on which the nozzle plate NP is disposed.

Referring to FIGS. 11 and 12, the first nozzle NZ1 may include a first nozzle hole NZ1-H. The first nozzle hole NZ1-H may be fluidly connected to the first path F1. For example, the first deposition material DM1 flowing through the first path F1 may be sprayed from the first nozzle NZ1 through the first nozzle hole NZ1-H. Referring to FIGS. 4 and 10 together, the first path F1 may be defined by the first crucible CR1 (or the first storage STP1), the first cover CV1, the partition wall PW, and the first nozzle hole NZ1-H. The first deposition material DM1 may be vaporized or sublimated in the first crucible CR1, and may flow along the lower surface of the first cover CV1, pass through the opening H, flow to an area (e.g., area SS1 shown in FIG. 10) of the upper portion of the storage STP through the opening H, and then flow to the first nozzle hole NZ1-H.

The second nozzle NZ2 may have a second nozzle hole NZ2-H. The second nozzle hole NZ2-H may be fluidly connected to the second path F2. For example, the second deposition material DM2 flowing through the second path F2 may be sprayed from the second nozzle NZ2 through the second nozzle hole NZ2-H. The second path F2 may be defined by the second crucible CR2 (or the second storage STP2), the second cover CV2, the partition wall PW, and the second nozzle hole NZ2-H. The second deposition material DM2 may be vaporized or sublimated in the second crucible CR2, and may flow along the lower surface of the second cover CV2, pass through the groove GRV, flow to an area (e.g., area SS2 shown in FIG. 10) of the upper portion of the storage STP through the groove GRV, and then flow to the second nozzle hole NZ2-H.

The first path F1 and the second path F2 may be fluidly separated from each other. The first deposition material DM1 and the second deposition material DM2 may not be mixed with each other in the housing HO before being sprayed through the first nozzle hole NZ1-H and the second nozzle hole NZ2-H.

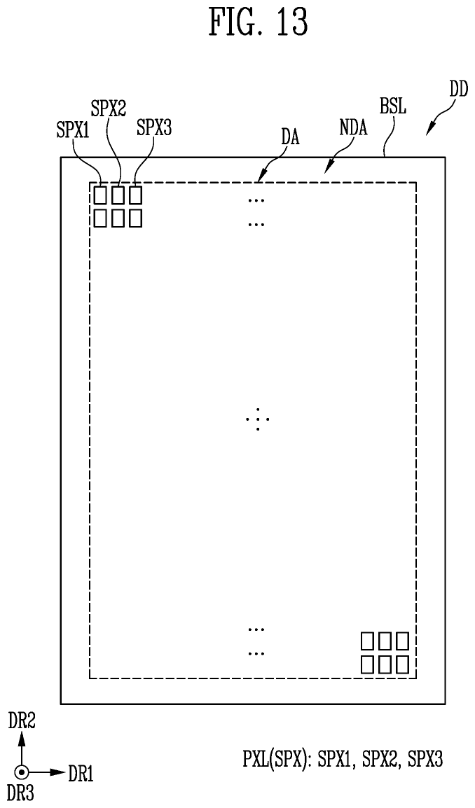

FIG. 13 is a schematic plan view illustrating a display device DD in accordance with an embodiment.

Referring to FIG. 13, the display device DD may include a base layer BSL, and pixels PXL on the base layer BSL. The display device DD may emit light. The display device DD may be manufactured by using the deposition source.

According to one or more embodiments, the display device DD may be a device that displays a video and/or a static image. The display device DD may be used not only as portable electronic devices such as a mobile phone, a smart phone, a tablet personal computer (a table PC), a smart watch, a watch phone, a mobile communication terminal, an electronic notebook, an electronic book, a portable multimedia player (PMP), a navigation device, and/or an ultra mobile PC (UMPC), but also as display screens of various suitable products such as a television, a notebook, a monitor, an advertisement panel, and an internet of things (IOT) device. Here, the application field of the display device DD is not limited to a specific example.

According to one or more embodiments, the display device DD may be formed of a rectangular panel having short sides extending in a first direction DR1, and long sides extending a second direction DR2 intersecting with the first direction DR1. Corners where the short sides extending in the first direction DR1 and the long sides extending in the second direction DR2 meet may be rounded to have a set or certain curvature or may be formed at a right angle. The plane shape of the display device DD is not limited to a rectangular shape, and may have other polygonal shapes, or a rounded shape such as a circular shape (e.g., a generally circular shape) or an elliptical shape. The display device DD may be formed to be planar, but it is not limited thereto. For example, the display device DD may include a curved surface which is formed on each of left and right side edges thereof and has a constant curvature or a suitably varying curvature. In embodiments, the display device DD may be formed to be flexible so that the display device DD can be bent, curved, folded, and/or rolled.

According to one or more embodiments, the display device DD may further include a driving circuit component (e.g., a scan driver and a data driver), lines, and pads to drive the pixels PXL.

The display device DD (or the base layer BSL) may include a display area DA and a non-display area NDA. The non-display area NDA may refer to an area other than the display area DA. The non-display area NDA may enclose at least a portion of the display area DA.

The base layer BSL may form a base surface of the display device DD. The base layer BSL may be a rigid or flexible substrate and/or film. For example, the base layer BSL may be a rigid substrate made of glass and/or reinforced glass, a flexible substrate (or a thin film) formed of plastic and/or metal, and/or at least one insulating layer (e.g., at least one electrically insulating layer). The material and/or properties of the base layer BSL are not particularly limited. According to one or more embodiments, the base layer BSL may be substantially transparent. Here, the words “substantially transparent” may mean that light can pass through the base layer BSL with a transmittance (e.g., a light transmittance) of a set or certain value or more. According to one or more embodiments, the base layer BSL may be translucent or opaque. Furthermore, the base layer BSL may include a reflective material (e.g., a light reflective material) depending on the embodiment.

The display area DA may refer to an area in which the pixels PXL are provided. The non-display area NDA may refer to an area in which the pixels PXL are not provided. The driving circuit component, the lines, and the pads which are connected to the pixels PXL of the display area DA may be in the non-display area NDA.

In accordance with an embodiment, the pixels PXL (or the sub-pixels SPX) may be in a stripe or PENTILE® arrangement structure (e.g., an RGBG matrix, RGBG structure, or RGBG matrix structure) or the like, but the present disclosure is not limited thereto. PENTILE® is a duly registered trademark of Samsung Display Co., Ltd. Various suitable embodiments may be applied to the present disclosure.

In accordance with an embodiment, each pixel PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one first sub-pixel SPX1, at least one second sub-pixel SPX2, and at least one third sub-pixel SPX3 may form a pixel unit which may emit various suitable colors of light.

For example, each of the first sub-pixel SPX1, the second sub-pixel SPX2, and the third sub-pixel SPX3 may emit a single color of light. For instance, the first sub-pixel SPX1 may be a red pixel configured to emit light in red (e.g., a first color), the second sub-pixel SPX2 may be a green pixel configured to emit light in green (e.g., a second color), and the third sub-pixel SPX3 may be a blue pixel configured to emit light in blue (e.g., a third color). In accordance with an embodiment, the number of second sub-pixels SPX2 may be greater than the number of first sub-pixels SPX1, or the number of third sub-pixels SPX3. The colors, types (or kinds), and/or numbers of first sub-pixels SPX1, second sub-pixels SPX2, and the third sub-pixels SPX3 which form each pixel unit are not limited to a specific example.

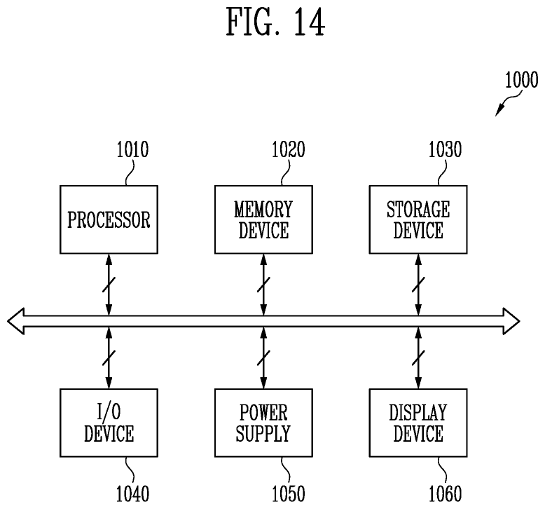

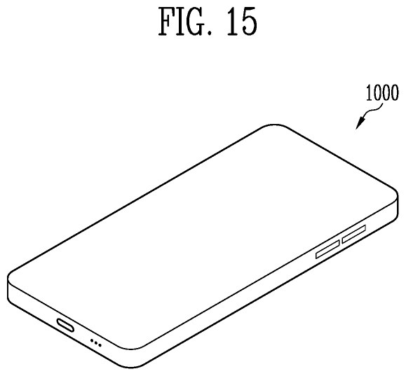

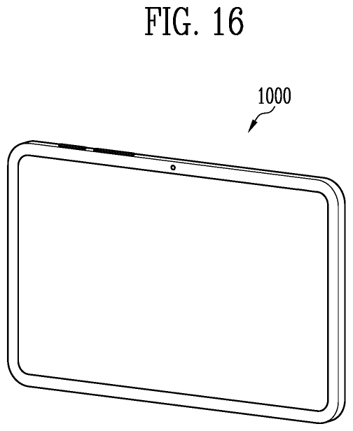

FIG. 14 is a schematic block diagram illustrating an electronic device 1000 including a display device in accordance with an embodiment. FIG. 15 is a schematic diagram illustrating an example where the electronic device 1000 of FIG. 14 is a smartphone. FIG. 16 is a schematic diagram illustrating an example where the electronic device 1000 of FIG. 14 is a tablet computer.

Referring to FIGS. 14 to 16, the electronic device 1000 may include a processor 1010, a memory device 1020, a storage device 1030, an input/output (I/O) device 1040, a power supply 1050, and a display device 1060. The display device 1060 may be the display device DD of FIG. 14. The electronic device 1000 may further include various ports for communication with a video card, a sound card, a memory card, a USB device, or other systems. In an embodiment, as illustrated in FIG. 15, the electronic device 1000 may be a smartphone. In an embodiment, as illustrated in FIG. 16, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

Various embodiments may provide a deposition source capable of preventing deposition materials from being mixed therein, and uniformly depositing different deposition materials onto a target substrate.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A deposition source comprising:
a housing;
a nozzle component disposed on the housing, and including a first nozzle and a second nozzle adjacent to the first nozzle;
a first storage disposed in the housing and that receives a first deposition material;
a second storage disposed in the housing and that receives a second deposition material; and
a cover disposed between the housing and the nozzle component, and including a first cover and a second cover,
wherein the first cover overlaps the first storage without overlapping the second storage, in a plan view.

2. The deposition source of claim 1, wherein
the first cover covers an upper portion of the first storage, and
the second cover covers an upper portion of the second storage.

3. The deposition source of claim 1, wherein
the first cover includes a first cover hole,
the first storage includes a first storage hole overlapping the first cover hole in a plan view,
the second cover includes a second cover hole, and
the second storage includes a second storage hole overlapping the second cover hole in a plan view.

4. The deposition source of claim 3, wherein
a first fastener is inserted into the first cover hole and the first storage hole,
a second fastener is inserted into the second cover hole and the second storage hole, and
each of the first fastener and the second fastener includes a bolt.

5. The deposition source of claim 1, wherein
the first storage includes:
a first crucible that receives the first deposition material; and
a first partition that divides an internal space of the first crucible,
the second storage includes:
a second crucible that receives the second deposition material; and
a second partition that divides an internal space of the second crucible,
a height of the first partition is shorter than a height of the first crucible, and
a height of the second partition is shorter than a height of the second crucible.

6. The deposition source of claim 5, wherein
the first cover does not contact the first partition, and
the second cover does not contact the second partition.

7. The deposition source of claim 5, wherein
the internal space of the first crucible is fluidly connected, and
the internal space of the second crucible is fluidly connected.

8. The deposition source of claim 1, further comprising:
a plate disposed on the cover, wherein
the plate has a plate-like structure extending in a first direction and a second direction intersecting with the first direction, and
the plate has a plurality of plate holes.

9. The deposition source of claim 1, further comprising:
a partition wall disposed between the first storage and the second storage.

10. The deposition source of claim 9, wherein
the first cover includes:
a first cover plate extending in a first direction and a second direction intersecting with the first direction; and
a first cover protrusion protruding from the first cover plate in a third direction perpendicular to the first direction and the second direction,
wherein the second cover includes:
a second cover plate extending in the first direction and the second direction; and
a second cover protrusion protruding from the second cover plate in the third direction,
wherein a side surface of the first cover protrusion contacts a first side surface of the partition wall, and
a side surface of the second cover protrusion contacts a second side surface of the partition wall different to the first side surface.

11. The deposition source of claim 1, further comprising:
a heater disposed adjacent to the housing, and including a first heater and a second heater, wherein
the first heater is connected to a first power supply, and that heats the first storage, and
the second heater is connected to a second power supply independent from the first power supply, and that heats the second storage.

12. The deposition source of claim 1, wherein
the housing includes a housing bottom, and a housing sidewall part bent and extending from the housing bottom,
the housing sidewall part includes a housing protrusion protruding toward a sidewall of the housing, and
the housing protrusion is disposed between the first storage and the second storage,
the deposition source further including an adiabatic plate disposed in the housing protrusion.

13. The deposition source of claim 1, wherein
a vacant space is defined between the first storage and the second storage, and
the deposition source further includes an adiabatic plate disposed in the vacant space.

14. The deposition source of claim 10, wherein
the first nozzle includes a first nozzle hole,
the second nozzle includes a second nozzle hole, and
the first nozzle and the second nozzle are alternately arranged.

15. The deposition source of claim 14, wherein
the first deposition material is sprayed from the first nozzle through a first path defined by the first storage, the first cover, the partition wall, and the first nozzle hole,
the second deposition material is sprayed from the second nozzle through a second path defined by the second storage, the second cover, the partition wall, and the second nozzle hole, and
the first path and the second path are fluidly separated from each other.

16. A deposition source comprising:
a housing;
a nozzle component disposed on the housing, and including a first nozzle and a second nozzle alternately arranged;
a first storage disposed in a first side of the housing and that receives a first deposition material;
a second storage disposed in a second side of the housing and that receives a second deposition material;
a partition wall disposed in the housing, and positioned between the first storage and the second storage; and
a heater disposed adjacent to the housing, and including a first heater and a second heater, wherein
the first heater is connected to a first power supply,
the second heater is connected to a second power supply different from the first power supply,
the first deposition material is sprayed from the first nozzle,
the second deposition material is sprayed from the second nozzle, and
the first deposition material and the second deposition material are prevented from being mixed with each other in the housing.

17. The deposition source of claim 16, further comprising:
a cover disposed between the housing and the nozzle component, and including a first cover and a second cover; and
a partition wall disposed between the first storage and the second storage, wherein
the first cover includes:
a first cover plate extending in a first direction and a second direction intersecting with the first direction; and
a first cover protrusion protruding from the first cover plate in a third direction perpendicular to the first direction and the second direction, and
the second cover includes:
a second cover plate extending in the first direction and the second direction; and
a second cover protrusion protruding from the second cover plate in the third direction,
the first cover plate covers an upper portion of the first storage,
the second cover plate covers an upper portion of the second storage,
a side surface of the first cover protrusion contacts at least a portion of a first side surface of the partition wall, and
a side surface of the second cover protrusion contacts at least a portion of a second side surface of the partition wall different to the first side surface.

18. The deposition source of claim 17, wherein
the first cover includes a first cover hole,
the first storage includes a first storage hole overlapping the first cover hole in a plan view,
the second cover includes a second cover hole,
the second storage includes a second storage hole overlapping the second cover hole in a plan view,
a first fastener is inserted into the first cover hole and the first storage hole,
a second fastener is inserted into the second cover hole and the second storage hole, and
each of the first fastener and the second fastener includes a bolt.

19. The deposition source of claim 16, further comprising:
a plate disposed under the nozzle component, wherein
the plate has a plate-like structure extending in a first direction and a second direction intersecting with the first direction, and
the plate has a plurality of plate holes.

20. The deposition source of claim 16, wherein
a vacant space is defined between the first storage and the second storage,
the deposition source further including an adiabatic plate disposed in the vacant space,
wherein the adiabatic plate includes a metallic material.

21. An electronic device, comprising:
a processor that provides input image data; and
a display device that displays an image based on the input image data,
wherein the display device is manufactured by using a deposition source according to claim 1.
